(19) United States
(12) Patent Application Publication
(10) Pub. No.: US 2026/0068535 A1
(43) Pub. Date: Mar. 5, 2026

(54) MEMORY DEVICE AND MANUFACTURING METHOD THEREOF

(71) Applicant: UNITED MICROELECTRONICS CORP., Hsin-Chu City (TW)

(72) Inventors: Wen-Wen Zhang, Changhua County (TW); Kun-Chen Ho, Tainan City (TW); Ya-Wei Shih, Tainan City (TW); Chung-Yi Chiu, Tainan City (TW)

(73) Assignee: UNITED MICROELECTRONICS CORP., Hsin-Chu City (TW)

(21) Appl. No.: 18/900,838

(22) Filed: Sep. 29, 2024

(30) Foreign Application Priority Data
Aug. 28, 2024 (TW) 113132399

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A memory device includes a magnetic tunneling junction (MTJ) structure, a top electrode, and a first cap layer. The MTJ structure is disposed above a substrate and includes a first tilted sidewall. The top electrode is disposed on the MTJ structure in a vertical direction and includes a second tilted sidewall. The first cap layer covers the top electrode and the MTJ structure. The first cap layer includes a first portion covering the first tilted sidewall in a horizontal direction and a second portion covering the second tilted sidewall in the horizontal direction. The first portion is partly located under the first tilted sidewall in the vertical direction. The second portion is partly located under the second tilted sidewall in the vertical direction. A thickness of the first portion in the horizontal direction is greater than a thickness of the second portion in the horizontal direction.

### BACKGROUND OF THE INVENTION

### 1. Field of the Invention

The present invention relates to a memory device and a manufacturing method thereof, and more particularly, to a memory device including a magnetic tunneling junction (MTJ) structure and a manufacturing method thereof.

### 2. Description of the Prior Art

There are essentially two types of data memory devices used in electronic products, non-volatile and volatile memory devices. Magnetic random access memory (MRAM) is a kind of non-volatile memory technology. Unlike current industry-standard memory devices, the MRAM uses magnetism instead of electrical charges to store data. In general, MRAM cells include a data layer and a reference layer. The data layer is composed of a magnetic material and the magnetization of the data layer can be switched between two opposing states by an applied magnetic field for storing binary information. The reference layer can be composed of a magnetic material in which the magnetization may be pinned. During the read operation, the resistance of the magnetic random access memory cell is different when the magnetization alignments of the data layer and the reference layer are the same or not, and the magnetization polarity of the data layer can be identified accordingly. The structure of MRAM devices will vary depending on the technology used to magnetize the data layer. Currently, spin-transfer torque (STT) magnetic random access memory and spin-orbit torque (SOT) magnetic random access memory are relatively common technology. How to improve the operation performance and/or the manufacturing yield of the MRAM device through structures and/or process design is an ongoing research direction for people in related fields.

### SUMMARY OF THE INVENTION

A memory device and a manufacturing method thereof are provided in the present invention. A top electrode having a tilted sidewall is used to improve related process conditions, and a first cap layer including portions with different thicknesses may be used to improve the protection effect and or the isolating effect to a magnetic tunneling junction structure.

According to an embodiment of the present invention, a memory device is provided. The memory device includes a magnetic tunneling junction (MTJ) structure, a top electrode, and a first cap layer. The MTJ structure is disposed above a substrate, and the MTJ structure includes a first tilted sidewall. The top electrode is disposed on the MTJ structure in a vertical direction, and the top electrode includes a second tilted sidewall. The first cap layer covers the top electrode and the MTJ structure, and the first cap layer includes a first portion and a second portion. The first portion covers the first tilted sidewall in a horizontal direction, and the first portion is partly located under the first tilted sidewall in the vertical direction. The second portion covers the second tilted sidewall in the horizontal direction, and the second portion is partly located under the second tilted sidewall in the vertical direction. A thickness of the first portion in the horizontal direction is greater than a thickness of the second portion in the horizontal direction.

According to an embodiment of the present invention, a manufacturing method of a memory device is provided. The manufacturing method includes the following steps. A magnetic tunneling junction (MTJ) structure and a top electrode are formed above a substrate. The MTJ structure includes a first tilted sidewall, the top electrode is located on the MTJ structure in a vertical direction, and the top electrode includes a second tilted sidewall. A first cap layer is formed covering the top electrode and the MTJ structure, and the first cap layer includes a first portion and a second portion. The first portion covers the first tilted sidewall in a horizontal direction, and the first portion is partly located under the first tilted sidewall in the vertical direction. The second portion covers the second tilted sidewall in the horizontal direction, and the second portion is partly located under the second tilted sidewall in the vertical direction. A thickness of the first portion in the horizontal direction is greater than a thickness of the second portion in the horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a memory device according to an embodiment of the present invention.

FIGS. 2-10 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

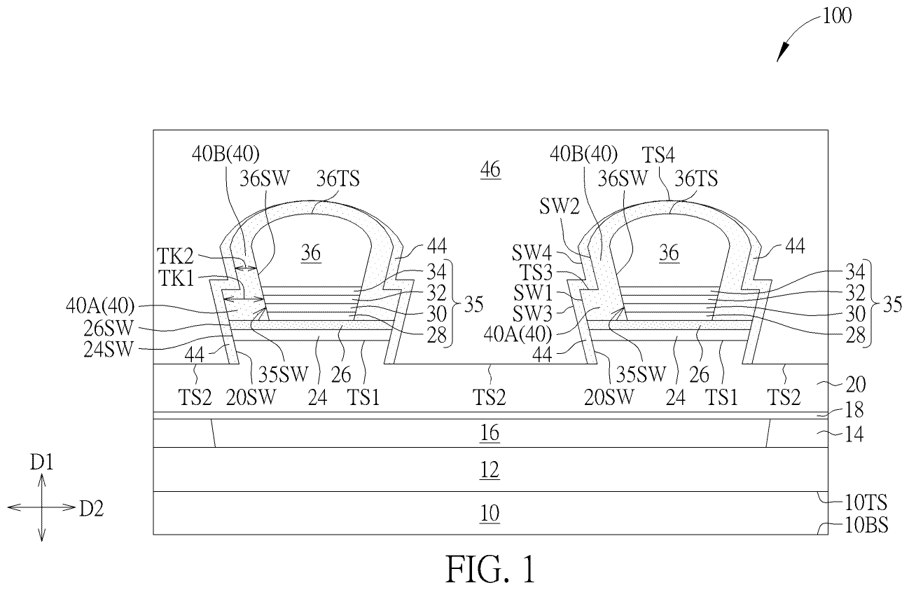

Please refer to FIG. 1. FIG. 1 is a schematic drawing illustrating a memory device 100 according to an embodiment of the present invention. As shown in FIG. 1, the memory device 100 includes a magnetic tunneling junction (MTJ) structure (such as a MTJ structure 35), a top electrode 36, and a first cap layer 40. The MTJ structure 35 is disposed above a substrate 10, and the MTJ structure 35 includes a first tilted sidewall (such as a tilted sidewall 35SW). The top electrode 36 is disposed on the MTJ structure 35 in a vertical direction D1, and the top electrode 36 includes a second tilted sidewall (such as a tilted sidewall 36SW). The first cap layer 40 covers the top electrode 36 and the MTJ structure 35, and the first cap layer 40 includes a first portion 40A and a second portion 40B. The first portion 40A covers the tilted sidewall 35SW in a horizontal direction (such as a horizontal direction D2), and the first portion 40A is partly located under the tilted sidewall 35SW in the vertical direction D1. The second portion 40B covers the tilted sidewall 36SW in the horizontal direction D2, and the second portion 40B is partly located under the tilted sidewall 36SW in the vertical direction D1. A thickness TK1 of the first portion 40A in the horizontal direction D2 is greater than a thickness TK2 of the second portion 40B in the horizontal direction D2. The related process conditions may be improved by controlling the shapes of the MTJ structure 35 and the top electrode 36, and the first cap layer 40 including portions with different thicknesses may be used to improve a protection effect and/or an isolating effect to the MTJ structure 35.

In some embodiments, the vertical direction D1 may be regarded as a thickness direction of the substrate 10. The substrate 10 may have a top surface 10TS and a bottom surface 10BS opposite to the top surface 10TS in the vertical direction D1, and the MTJ structures 35, the top electrode 36, and the first cap layer 40 described above may be disposed at the side of the top surface 10TS. A horizontal direction substantially orthogonal to the vertical direction D1 (such as the horizontal direction D2 or other horizontal directions) may be substantially parallel with the top surface 10TS and/or the bottom surface 10BS of the substrate 10, but not limited thereto. Additionally, in this description, a distance between the bottom surface 10BS of the substrate 10 and a relatively higher location and/or a relatively higher part in the vertical direction D1 may be greater than a distance between the bottom surface 10BS of the substrate 10 and a relatively lower location and/or a relatively lower part in the vertical direction D1. The bottom or a lower portion of each component may be closer to the bottom surface 10BS of the substrate 10 in the vertical direction D1 than the top or upper portion of this component. Another component disposed above a specific component may be regarded as being relatively far from the bottom surface 10BS of the substrate 10 in the vertical direction D1, and another component disposed under a specific component may be regarded as being relatively close to the bottom surface 10BS of the substrate 10 in the vertical direction D1. It is worth noting that, in this description, a top surface of a specific component may include but is not limited to the topmost surface of this component in the vertical direction D1, and a bottom surface of a specific component may include but is not limited to the bottommost surface of this component in the vertical direction D1. Additionally, in this description, the condition that a certain component is disposed between two other components in a specific direction may include but is not limited to a condition that the certain component is sandwiched between the two other components in the specific direction.

It is worth noting that, each tilted sidewall in this description may include at least a portion of an inverted chamfer structure, and a width of a component including the tilted sidewall may gradually and/or continuously decrease from the topmost end of the tilted sidewall in the vertical direction D1 to the bottommost end of the tilted sidewall in the vertical direction D1 accordingly. In addition, the width of each component in this description may include but is not limited to the width in the horizontal direction D2, and a width of a specific component in the horizontal direction D2 may also be regarded as a length of this component in the horizontal direction D2. For example, the width of the top electrode 36 may gradually and/or continuously decrease from the topmost end of the tilted sidewall 36SW in the vertical direction D1 to the bottommost end of the tilted sidewall 36SW in the vertical direction D1. In some embodiments, the top electrode 36 may further include a curved top surface 36TS, the curved top surface 36TS may protrude upwards in the vertical direction D1, and the curved top surface 36TS may directly connected with the tilted sidewall 36SW. Therefore, a width of the curved top surface 36TS may be substantially equal to a width of the top electrode 36 at the topmost end of the tilted sidewall 36SW, and the width of the curved top surface 36TS may be greater than a bottom width of the top electrode 36. In addition, a width of the MTJ structure 35 may gradually and/or continuously decrease from the topmost end of the tilted sidewall 35SW in the vertical direction D1 to the bottommost end of the tilted sidewall 35SW in the vertical direction D1. A top width of the MTJ structure 35 may be less than or substantially equal to the bottom width of the top electrode 36, and the top width of the MTJ structure 35 may be greater than a bottom width of the MTJ structure 35. In some embodiments, the MTJ structures 35 may include a free layer 28, a barrier layer 30, a reference layer 32, and a cap layer 34 stacked sequentially from bottom to top, but not limited thereto. The top width of the MTJ structure 35 may be regarded as a length of a top surface of the cap layer 34 in the horizontal direction D2, and the bottom width of the MTJ structure 35 may be regarded as a length of a bottom surface of the free layer 28 in the horizontal direction D2, but not limited thereto. In addition, a sidewall of the free layer 28, a sidewall of the barrier layer 30, a sidewall of the reference layer 32, and a sidewall of the cap layer 34 may be a portion of the tilted sidewall 35SW, respectively, and the free layer 28, the barrier layer 30, the reference layer 32, and the cap layer 34 may have a structure that is wide at the top and narrow at the bottom, respectively.

Because of the influence of the tilted sidewall 36SW of the top electrode 36 and the tilted sidewall 35SW of the MTJ structure 35, the first portion 40A of the first cap layer 40 covering the tilted sidewall 35SW may be partly located directly under the tilted sidewall 35SW in the vertical direction D1, and the second portion 40B of the first cap layer 40 covering the tilted sidewall 36SW may be partly located directly under the tilted sidewall 36SW in the vertical direction D1. In addition, the first portion 40A of the first cap layer 40 may include a third tilted sidewall (such as a tilted sidewall SW1) and a top surface TS3, the second portion 40B of the first cap layer 40 may include a fourth tilted sidewall (such as a tilted sidewall SW2), and the top surface TS3 may be directly connected with the tilted sidewall SW1 and the tilted sidewall SW2, respectively. The tilted sidewall SW1 may be substantially parallel with the tilted sidewall 35SW of the MTJ structure 35, and the tilted sidewall SW2 may be substantially parallel with the tilted sidewall 36SW of the top electrode 36, but not limited thereto. The tilted sidewall SW1 may be located directly under the top surface TS3 in the vertical direction D1, and the tilted sidewall SW2 may be located directly above the top surface TS3 in the vertical direction D1. In some embodiments, the first cap layer 40 covering the top electrode 36 in the vertical direction D1 may include a top surface TS4 directly connected with the tilted sidewall SW2, and the top surface TS4 may include a curved top surface, but not limited thereto.

In some embodiments, the memory device 100 may further include a bottom electrode 24 and a spin-orbit torque (SOT) layer (such as a SOT layer 26) disposed above the substrate 10. The MTJ structure 35 may be disposed on the SOT layer 26 in the vertical direction D1, and the bottom electrode 24 may be disposed under the SOT layer 26 in the vertical direction D1. The SOT layer 26 may include a fifth tilted sidewall (such as a tilted sidewall 26SW), the bottom electrode 24 may include a sixth tilted sidewall (such as a tilted sidewall 24SW), the tilted sidewall 26SW may be located under the first portion 40A of the first cap layer 40 in the vertical direction D1 (such as being located directly under the first portion 40A in the vertical direction D1), and the tilted sidewall 24SW may be located under the SOT layer 26 in the vertical direction D1 (such as being located directly under the SOT layer 26 in the vertical direction D1). A width of the SOT layer 26 may gradually and/or continuously decrease from the topmost end of the tilted sidewall 26SW in the vertical direction D1 to the bottommost end of the tilted sidewall 26SW in the vertical direction D1, and a width of the bottom electrode 24 may gradually and/or continuously decrease from the topmost end of the tilted sidewall 24SW in the vertical direction D1 to the bottommost end of the tilted sidewall 24SW in the vertical direction D1. A top width of the SOT layer 26 may be greater than a bottom width of the SOT layer 26, a top width of the bottom electrode 24 may be greater than a bottom width of the bottom electrode 24, the top width of the SOT layer 26 is greater than the width of the MTJ structure, and the top width of the bottom electrode 24 may be less than or substantially equal to the bottom width of the SOT layer 26, but not limited thereto. The first portion 40A of the first cap layer 40 may be partly sandwiched between the tilted sidewall 35SW and the SOT layer 26 in the vertical direction D1 and partly sandwiched between the tilted sidewall 36SW and the SOT layer 26 in the vertical direction D1.

In some embodiments, the memory device 100 may further include a dielectric layer 12, a dielectric layer 14, a connection structure 16, a stop layer 18, a dielectric layer 20, a second cap layer 44, and an interlayer dielectric layer 46. The dielectric layer 12 is disposed above the substrate 10, the dielectric layer 14 is disposed on the dielectric layer 12, and the connection structure 16 is disposed in the dielectric layer 14. The stop layer 18 may cover the connection structure 16 and the dielectric layer 14, the dielectric layer 20 is disposed on the stop layer 18, and the bottom electrode 24 may be disposed on the dielectric layer 20. In some embodiments, the bottom electrode 24 may be electrically connected with the connection structure 16 via a connection structure disposed in the dielectric layer 20 and the stop layer 18 (not illustrated), and the connection structure 16 and the connection structure disposed in the dielectric layer 20 and the stop layer 18 may be regarded as a trench conductor and a via conductor, respectively, but not limited thereto. In some embodiments, a top surface TS1 of the dielectric layer 20 located under the bottom electrode 24 in the vertical direction D1 may be higher than a top surface of other portions of the dielectric layer 20 (such as a top surface TS2) in the vertical direction D1, and the second cap layer 44 may cover the first cap layer 40, the tilted sidewall 26SW of the SOT layer 26, the tilted sidewall 24SW of the bottom electrode 24, and a tilted sidewall 20SW of the dielectric layer 20 located under the bottom electrode 24 in the vertical direction D1. The interlayer dielectric layer 46 may cover the second cap layer 44 and the top surface TS2 of the dielectric layer 20. The second cap layer 44 may cover the top surface TS4, the tilted sidewall SW2, the top surface TS3, and the tilted sidewall SW1 of the first cap layer 40, and the second cap layer 44 may include a tilted sidewall SW3 located corresponding to the tilted sidewall SW1, the tilted sidewall 26SW, the tilted sidewall 24SW, and the tilted sidewall 20SW and a tilted sidewall SW4 located corresponding to the tilted sidewall SW2, but not limited thereto. The tilted sidewall SW3 may be parallel with the tilted sidewall SW1, the tilted sidewall 26SW, the tilted sidewall 24SW, and/or the tilted sidewall 20SW substantially, and the tilted sidewall SW4 may be parallel with the tilted sidewall SW2 substantially, but not limited thereto. In addition, the second cap layer 44 may be partly disposed under the tilted sidewall SW1, the tilted sidewall 26SW, the tilted sidewall 24SW, and the tilted sidewall 20SW in the vertical direction D21, respectively, such as being party disposed directly under each tilted sidewall described above in the vertical direction D1.

In some embodiments, the substrate 10 may include a semiconductor substrate or a non-semiconductor substrate. The semiconductor substrate may include a silicon substrate, a silicon germanium semiconductor substrate or a silicon-on-insulator (SOI) substrate, and the non-semiconductor substrate may include a glass substrate, a plastic substrate, or a ceramic substrate, but not limited thereto. For example, when the substrate 10 includes a semiconductor substrate, a plurality of field effect transistors (not illustrated), a dielectric layer covering the field effect transistors (such as the dielectric layer 12 and the dielectric layer 14), and the connection structure 16 electrically connected with the field effect transistors may be disposed on the semiconductor substrate according to some considerations, and the bottom electrode 24 may be electrically connected with a specific transistor via the connection structure 16, but not limited thereto.

In some embodiments, electrical current may be formed in the bottom electrode 24 via two connection structures connected with the bottom electrode 24 (such as the connection structures disposed in the dielectric layer 20 and the stop layer 18), and the magnetic moment and the magnetization effect influencing the MTJ structure 35 may be formed by the electrical current passing through the SOT layer 26. The SOT layer 26 may include a SOT material, and the SOT material may be defined as a material capable of generating the spin Hall effect and/or a material with greater spin-orbit coupling strength, so as to generate spin-orbit torque on the free layer 28 and change the direction of the magnetic torque of the free layer 28. For example, the SOT material may include hafnium (Hf), rhenium (Re), ruthenium (Ru), gold (Au), platinum (Pt), tantalum (Ta), tungsten (W), iridium (Ir), palladium (Pd), an alloy of the materials described above (such as IrPt, PtAu, PtPd, BiSb, and so forth), a compound of the materials described above (such as PtS, WTe₂, and so forth), or other suitable materials (such as BiSb and BiₓSe₁₋ₓ). The free layer 28 and the reference layer 32 may include ferromagnetic materials, such as iron, cobalt, nickel, cobalt-iron (CoFe), cobalt-iron-boron (CoFeB), or other suitable ferromagnetic materials. In some embodiments, the reference layer 32 and an antiferromagnetic layer (not illustrated) may constitute a pinned layer with fixed direction of magnetic torque. The antiferromagnetic layer may include antiferromagnetic materials, such as iron manganese (FeMn), platinum manganese (PtMn), iridium manganese (IrMn), nickel oxide (NiO), a cobalt/platinum (Co/Pt) multilayer, or other suitable antiferromagnetic materials. The barrier layer 30 may include insulation materials, such as magnesium oxide (MgO), aluminum oxide, or other suitable insulation materials. The cap layer 34 may include ruthenium or other suitable electrically conductive materials.

In some embodiments, the first cap layer 40 and the second cap layer 44 may include silicon nitride or other suitable cap materials, and the material composition of the first cap layer 40 may be identical to or different from the material composition of the second cap layer 44 according to some design considerations. The dielectric layer 12, the dielectric layer 14, and the dielectric layer 20 may include an oxide dielectric material, a low dielectric constant dielectric material (such as a dielectric material with dielectric constant lower than 2.9, but not limited thereto), or other suitable dielectric materials. The interlayer dielectric layer 46 may include a low dielectric constant dielectric material or an ultra low dielectric constant (ULK) dielectric material (such as a dielectric material with dielectric constant lower than 2.7, but not limited thereto). The connection structure 16 may include a barrier layer and an electrically conductive material disposed on the barrier layer. The barrier layer may include titanium (Ti), titanium nitride, tantalum, tantalum nitride, or other suitable electrically conductive battier materials, and the electrically conductive material may include tungsten, copper, aluminum, titanium aluminide, cobalt tungsten phosphide, or other suitable electrically conductive materials with relatively low electrical resistivity. The stop layer 18 may include nitrogen doped carbide (NDC), silicon nitride, silicon carbon nitride (SiCN), or other suitable materials. The bottom electrode 24 may include tantalum, tantalum nitride, platinum, copper, gold, aluminum, or other suitable electrically conductive materials. The top electrode 36 may include tantalum, tantalum nitride, titanium, titanium nitride, platinum, copper, gold, aluminum, or other suitable electrically conductive materials.

In some embodiments, the bottom electrode 24, the SOT layer 26, the MTJ structure 35, and the top electrode 36 may constitute a memory cell, a plurality of memory cells may be disposed on the substrate 10, and the MTJ structure 35 with the tilted sidewall, the top electrode 36 with the tilted sidewall, and the first cap layer 40 including portions with different thicknesses may be used to improve the protection performance and/or the isolation effect to the MTJ structures 35 without increasing the area occupied by each of the memory cells. In addition, a contact area of the top electrode 36 including the curved top surface 36TS and the tilted sidewall 36SW may be greater for improving the process window of forming the contact structure located corresponding to the top electrode 36, the related manufacturing yield may be enhanced accordingly, and the contact structure may become larger for reducing the contact resistance.

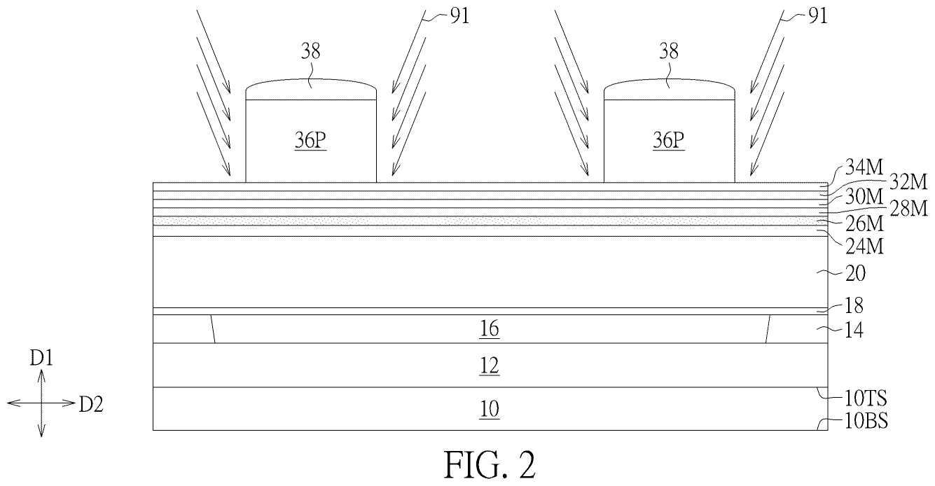

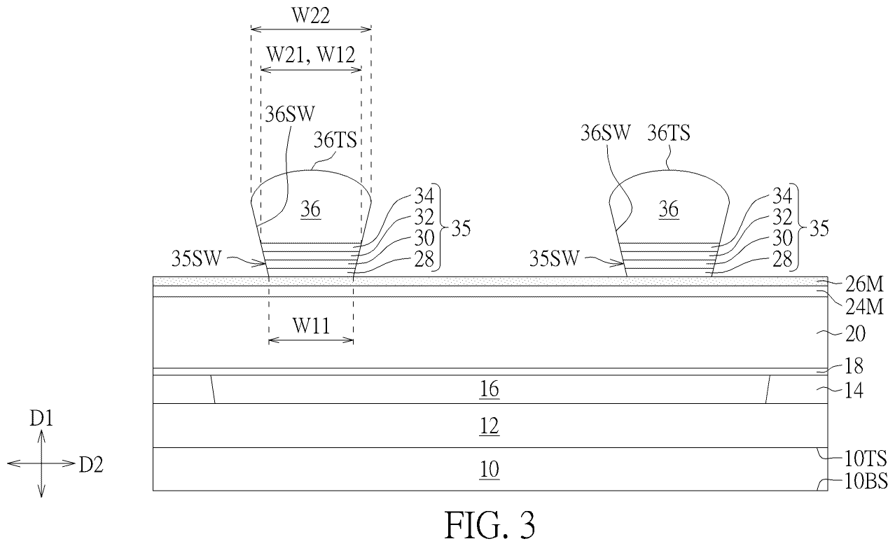

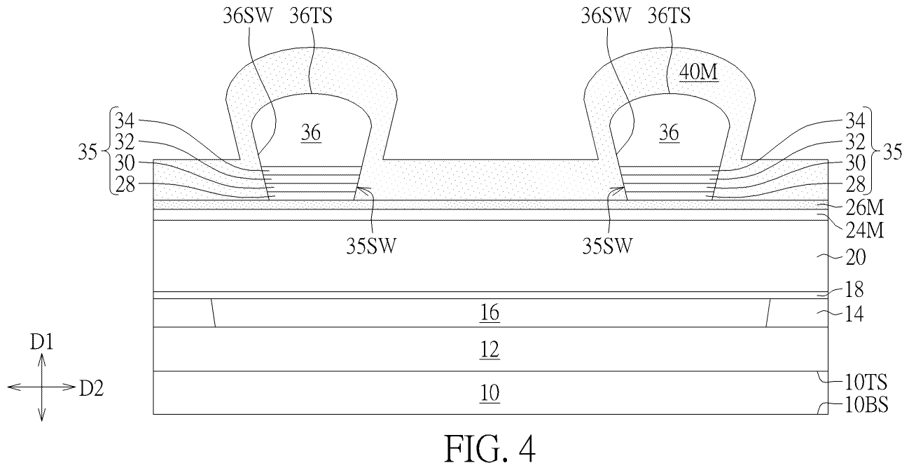

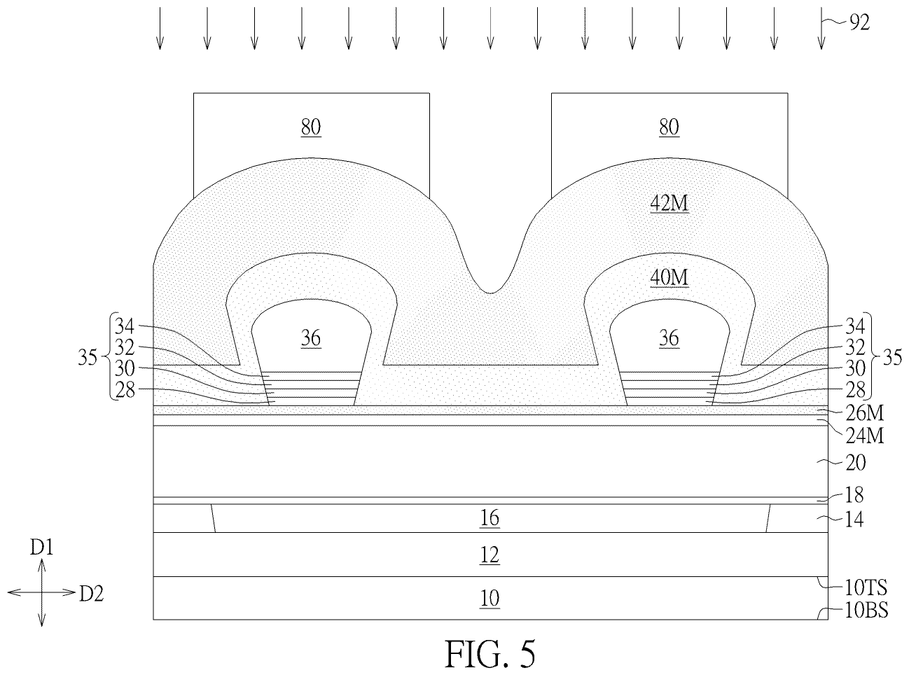

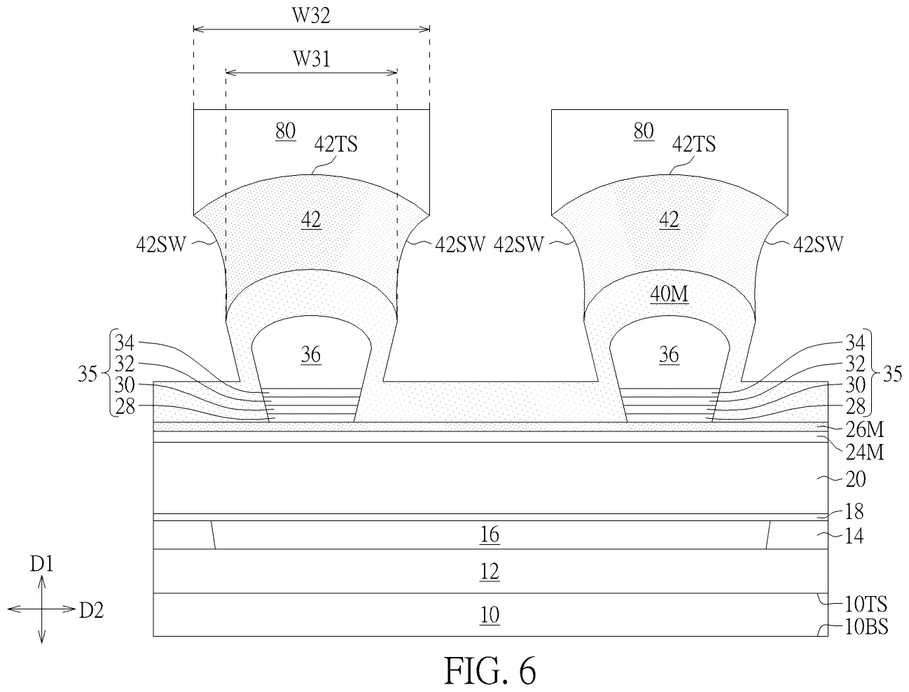

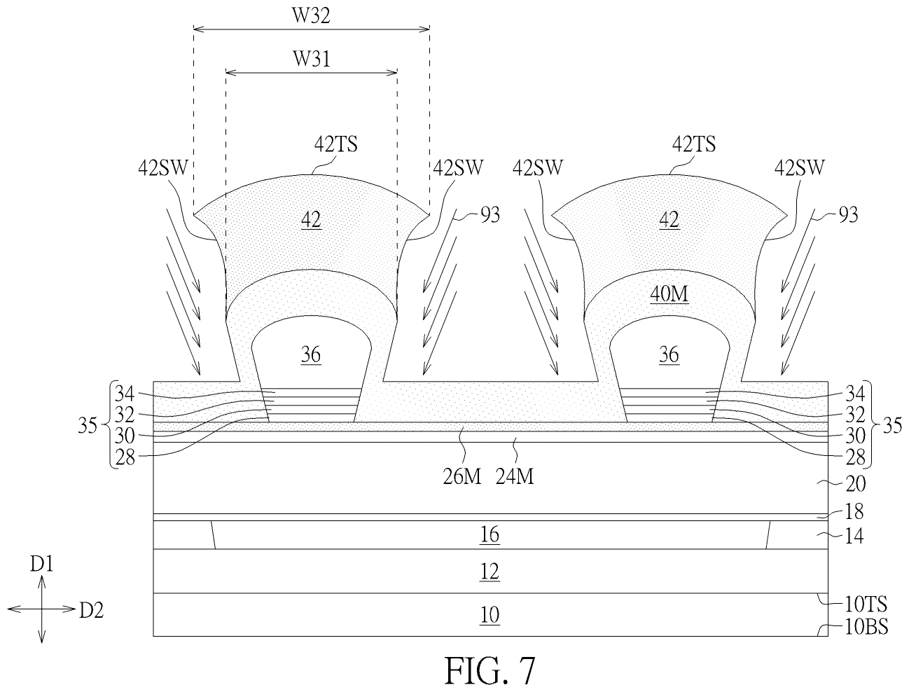

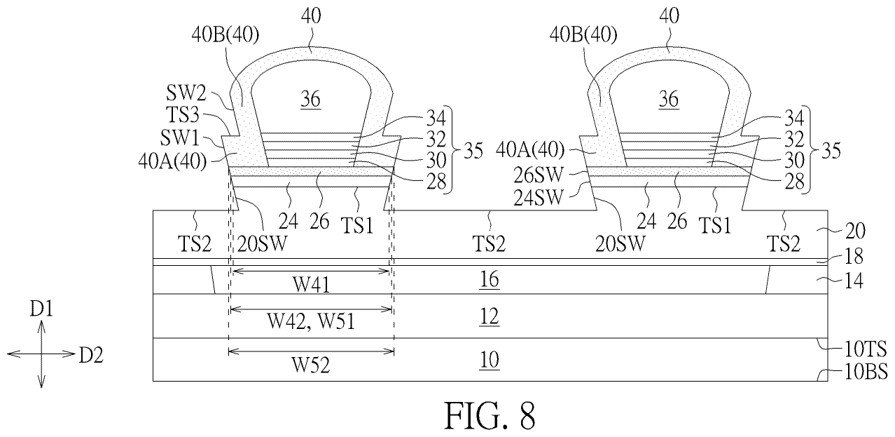

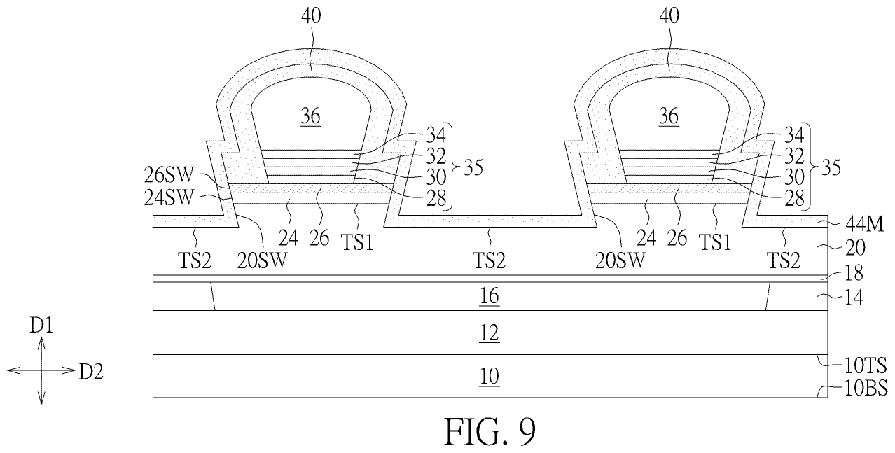

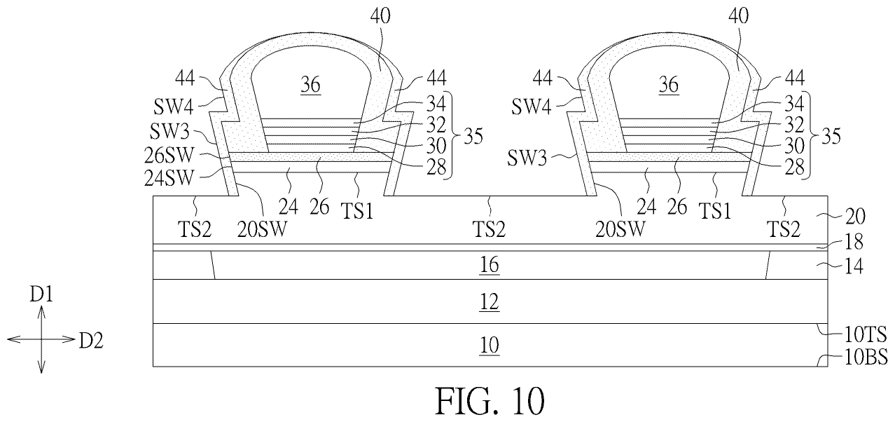

Please refer to FIGS. 1-10. FIGS. 2-10 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9. In some embodiments, FIG. 1 may be regarded as a schematic drawing in a step subsequent to FIG. 10, but not limited thereto. As shown in FIG. 1, the manufacturing method in this embodiment includes the following steps. The magnetic tunneling junction structure (such as the MTJ structure 35) and the top electrode 36 are formed above the substrate 10. The MTJ structure 35 includes the first tilted sidewall (such as the tilted sidewall 35SW), the top electrode 36 is located on the MTJ structure 35 in the vertical direction D1, and the top electrode 36 includes the second tilted sidewall (such as the tilted sidewall 36SW). The first cap layer 40 is formed covering the top electrode 36 and the MTJ structure 35. The first cap layer 40 includes the first portion 40A and the second portion 40B. The first portion 40A covers the tilted sidewall 35SW in the horizontal direction D2, and the first portion 40A is partly located under the tilted sidewall 35SW in the vertical direction D2. The second portion 40B covers the tilted sidewall 36SW in the horizontal direction D2, and the second portion 40B is partly located under the tilted sidewall 36SW in the vertical direction D1. The thickness TK1 of the first portion 40A in the horizontal direction D1 is greater than a thickness TK2 of the second portion 40B in the horizontal direction D2.

Specifically, the manufacturing method in this embodiment may include but is not limited to the following steps. As shown in FIG. 2, active components (such as the transistors described above), passive components, or other required circuit structures may be formed on the substrate 10, and the dielectric layer 12, the dielectric layer 14, the connection structures 16, the stop layer 18, and the dielectric layer 20 described above may then be formed. Subsequently, an electrically conductive material 24M, a SOT material 26M, a ferromagnetic material 28M, a barrier material 30M, a ferromagnetic material 32M, and a cap material 34M may be sequentially formed above the dielectric layer 20. Afterwards, a patterned electrically conductive material 36P may be formed on the cap material 34M. In some embodiments, an electrically conductive material may be formed on the cap material 34M, and a mask layer 38 may be formed on this electrically conductive material. A patterning process (such as a reactive ion etching (RIE) process, but not limited thereto) using a patterned mask layer (such as a patterned photoresist layer, not illustrated) as a mask may then be performed to the mask layer 38 and the electrically conductive material for forming the patterned electrically conductive material 36P. The mask layer 38 may be removed after this patterning process or remain on the patterned electrically conductive material 36P after this patterning process.

The mask layer 38 may include an oxide mask material (such as silicon oxide) or other suitable mask materials. As shown in FIG. 2 and FIG. 3, an etching process 91 using the patterned electrically conductive material 36P and/or the mask layer 38 as a mask may then be performed for patterning the cap material 34M, the ferromagnetic material 32M, the barrier material 30M, and the ferromagnetic material 28M and forming the MTJ structure 35 including the cap layer 34, the reference layer 32, the barrier layer 30, and the free layer 28 on the SOT material 26M, and the patterned electrically conductive material 36P may be partially etched by the etching process 91 to be the top electrode 36 located above the MTJ structure 35. In other words, the SOT material 26M may be formed above the substrate 10 before the MTJ structure 35 is formed, and the electrically conductive material 24M may be formed above the substrate 10 before the SOT material 26M is formed. The SOT material 26M may be formed on the electrically conductive material 24M, and the MTJ structure 35 and the top electrode 36 may be formed on the SOT material 26M. In some embodiments, the etching process 91 may include a tilted ion beam etching (IBE) process or other suitable etching approaches for forming the MTJ structure 35 with the tilted sidewall 35SW and the top electrode 36 with the titled sidewall 36SW, and the top electrode 36 may have the curved top surface 36TS protruding upwards by adjusting the process parameters of the etching process 91 for enhancing the sidewall etching efficiency in the IBE process, but not limited thereto. In some embodiments, a width W22 of the curved top surface 36TS may be greater than the bottom width of the top electrode 36 (such as a width W21), and the top width of the MTJ structure 35 (such as a width W12) may be greater than the bottom width of the MTJ structure 35 (such as a width W11).

As shown in FIGS. 2-4, after the MTJ structure 35 and the top electrode 36 are formed, a cap material 40M may be formed covering the SOT material 26M, the MTJ structure 35, and the top electrode 36, and the cap material 40M may be substantially formed conformally on the top surface of the SOT material 26M, the tilted sidewall 35SW of the MTJ structure 35, the tilted sidewall 36SW of the top electrode 36, and the curved top surface 36TS of the top electrode 36. Subsequently, as shown in FIG. 7 and FIG. 8, an oxide mask layer 42 may be formed on the cap material 40M, and an etching process 93 using the oxide mask layer 42 as a mask may be performed to the cap material 40M, the SOT material 26M, and the electrically conductive material 24M. The cap material 40M may be patterned to be the first cap layer 40 described above by the etching process 93, the SOT material 26M may be patterned to be the SOT layer 26 described above by the etching process 93, and the electrically conductive material 24M may be patterned to be the bottom electrode 24 described above by the etching process 93. In some embodiments, the oxide mask layer 42 may include a concave sidewall 42SW and a curved top surface 42TS, the curved top surface 42TS may protrude upwards in the vertical direction D1 and be directly connected with the concave sidewall 42SW, and a width W32 of the curved top surface 42TS may be greater than a bottom width of the oxide mask layer 42 (such as a width W31). In addition, the width W31 may also be regarded as a length of a portion of the mask material 40M directly contacting the oxide mask layer 42 in the horizontal direction D2, but not limited thereto. The etching process 93 may include a tilted ion beam etching process or other suitable etching approaches for being performed along with the shape of the oxide mask layer 42, so as to etch the cap material 40M, the SOT material 26M, and the electrically conductive material 24M and form the first cap layer 40, the SOT layer 26, and the bottom electrode 24 with the shape characteristics described above.

In the present invention, a method of forming the oxide mask layer 42 may include but is not limited to the following steps. As shown in FIG. 5, an oxide material 42M may be formed on the cap material 40M, and a patterned mask layer 80 may be formed on the oxide material 42M. The oxide material 42M may be substantially formed conformally on the cap material 40M, and the patterned mask layer 80 may include photoresist or other suitable mask materials. Subsequently, as shown in FIG. 5 and FIG. 6, a wet etching process 92 using the patterned mask layer 80 as a mask may be performed to the oxide material 42M, and the oxide material 42M may be patterned to be the oxide mask layer 42 by the wet etching process 92. The oxide material 42M may include tetraethoxysilane (TEOS) oxide or other suitable oxide. The patterned mask layer 80 may be removed after the wet etching process 92, and the wet etching process 92 may include a buffer oxide etchant (BOE) etching process or other suitable wet etching approaches with higher etching selectivity to the oxide material 42M for reducing etching damage to the cap material 40M in the process of forming the oxide mask layer 42 and forming the oxide mask layer 42 with the shape characteristics described above. The oxide mask layer 42 including the concave sidewall 42SW may be formed by the wet etching process 92 with isotropic etching property, and the width W32 of the curved top surface 42TS may be greater than the bottom width of the oxide mask layer 42 by controlling the width of the patterned mask layer 80 and performing the wet etching process 92 with the patterned mask layer 80. In addition, as shown in FIG. 7 and FIG. 8, for ensuring the patterning performance to the electrically conductive material 24M, the etching process 93 may further etch downwards to the dielectric layer 20, and the tilted sidewall 20SW may be formed accordingly. Therefore, a part of the dielectric layer 20 may be removed by the etching process 93, and the top surface TS1 of the dielectric layer 20 located under the bottom electrode 24 in the vertical direction D1 may be higher than the top surface TS2 of other portions of the dielectric layer 20 in the vertical direction D1.

It is worth noting that, the etching damage to the cap material 40M in the process of forming the oxide mask layer 42 (such as the wet etching process 92 illustrated in FIG. 5) may be reduced by the manufacturing approach described above, and the etching depth may be controlled more easily in the etching process 93 performed subsequently. Therefore, there is no need to increase the thickness of the dielectric layer 20 to compensate for the etching loading effect, and that will be of positive help in controlling the etching condition of the etching process 93. Relatively, when the oxide mask layer is defined by a dry etching process with a patterned photoresist layer and a bottom anti-reflection layer, etching damage generated to the cap material 40M will be uneven in different regions because of the influence of loading effect, and the controlling of etching condition in the subsequent IBE process will be affected accordingly. In addition, the method of forming the first cap layer 40 in the present invention may include but is not limited to the steps shown in FIGS. 4-8, and the first cap layer 40, the SOT layer 26, and the bottom electrode 24 illustrated in FIG. 8 may also be formed by other suitable approaches according to some design considerations.

As shown in FIG. 7 and FIG. 8, the tilted IBE process performed with the oxide mask layer 42 having the shape characteristics described above may be used to form the first cap layer 40 including the tilted sidewall SW1 and the tilted sidewall SW2, the SOT layer 26 including the tilted sidewall 26SW, the bottom electrode 24 including the tilted sidewall 24SW, and the tilted sidewall 20SW. The top width of the SOT layer 26 (such as a width W52) may be greater than the bottom width of the SOT layer 26 (such as a width W51), and the top width of the bottom electrode 24 (such as a width W42) may be greater than the bottom width of the bottom electrode 24 (such as a width W41). As shown in FIG. 9 and FIG. 10, after the first cap layer 40, the SOT layer 26, and the bottom electrode 24 are formed, the second cap layer 44 may be formed covering the first cap layer 40, the tilted sidewall 26SW of the SOT layer 26, the tilted sidewall 24SW of the bottom electrode 24, and the tilted sidewall 20SW of the dielectric layer 20. In some embodiments, a cap material 44M may be formed covering the first cap layer 40, the tilted sidewall 26SW of the SOT layer 26, the tilted sidewall 24SW of the bottom electrode 24, and the dielectric layer 20, an etching back process may then be performed to the cap material 44M, and the cap material 44M may be patterned to be the second cap layer 44 by this etching back process, but not limited thereto. In some embodiments, the topmost portion of the top surface TS4 of the first cap layer 40 is not covered by the second cap layer 44, but not limited thereto. As shown in FIG. 10 and FIG. 1, after the second cap layer 44 is formed, the interlayer dielectric layer 46 described above may be formed for forming the memory device 100 illustrated in FIG. 1.

To summarize the above descriptions, in the memory device and the manufacturing method thereof according to the present invention, the top electrode including the curved top surface and the tilted sidewall may be used to improve the process window of forming the corresponding contact structure and/or the electrically connection between the top electrode and the corresponding contact structure, and the first cap layer disposed corresponding to the tilted sidewalls of the top electrode and the MTJ structure may include portions with different thicknesses for improving the protection performance and/or the isolation effect to the MTJ structure. In addition, the wet etching process with higher etching selectivity may be used to define the oxide mask layer for reducing the etching damage to the cap material. The controlling of the process condition of the subsequent etching process for defining the first cap layer, the SOT layer, and the bottom electrode may be improved, and the manufacturing yield may be enhanced and/or the manufacturing cost may be reduced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device, comprising:
a magnetic tunneling junction (MTJ) structure disposed above a substrate, wherein the MTJ structure comprises a first tilted sidewall;
a top electrode disposed on the MTJ structure in a vertical direction, wherein the top electrode comprises a second tilted sidewall; and
a first cap layer covering the top electrode and the MTJ structure, wherein the first cap layer comprises:
a first portion covering the first tilted sidewall in a horizontal direction, wherein the first portion is partly located under the first tilted sidewall in the vertical direction; and
a second portion covering the second tilted sidewall in the horizontal direction, wherein the second portion is partly located under the second tilted sidewall in the vertical direction, and a thickness of the first portion in the horizontal direction is greater than a thickness of the second portion in the horizontal direction.

2. The memory device according to claim 1, wherein the first portion of the first cap layer comprises a third tilted sidewall and a top surface, the second portion of the first cap layer comprises a fourth tilted sidewall, and the top surface is connected with the third tilted sidewall and the fourth tilted sidewall, respectively.

3. The memory device according to claim 2, wherein the third tilted sidewall is located directly under the top surface in the vertical direction, and the fourth tilted sidewall is located directly above the top surface in the vertical direction.

4. The memory device according to claim 1, wherein the top electrode further comprises a curved top surface connected with the second tilted sidewall, and a width of the curved top surface is greater than a bottom width of the top electrode.

5. The memory device according to claim 1, wherein a top width of the MTJ structure is greater than a bottom width of the MTJ structure.

6. The memory device according to claim 1, further comprising:
a spin-orbit torque (SOT) layer disposed above the substrate, wherein the MTJ structure is disposed on the SOT layer in the vertical direction, and the SOT layer comprises a fifth tilted sidewall located under the first portion of the first cap layer in the vertical direction.

7. The memory device according to claim 6, wherein a top width of the SOT layer is greater than a bottom width of the SOT layer.

8. The memory device according to claim 6, wherein the first portion of the first cap layer is partly sandwiched between the first tilted sidewall and the SOT layer in the vertical direction and partly sandwiched between the second tilted sidewall and the SOT layer in the vertical direction.

9. The memory device according to claim 6, further comprising:
a bottom electrode disposed under the SOT layer in the vertical direction, wherein the bottom electrode comprises a sixth tilted sidewall located under the SOT layer in the vertical direction; and
a second cap layer covering the first cap layer, the fifth tilted sidewall, and the sixth tilted sidewall, wherein the second cap layer is partly disposed under the fifth tilted sidewall in the vertical direction and partly disposed under the sixth tilted sidewall in the vertical direction.

10. The memory device according to claim 9, wherein a top width of the bottom electrode is greater than a bottom width of the bottom electrode.

11. A manufacturing method of a memory device, comprising:
forming a magnetic tunneling junction (MTJ) structure and a top electrode above a substrate, wherein the MTJ structure comprises a first tilted sidewall, the top electrode is located on the MTJ structure in a vertical direction, and the top electrode comprises a second tilted sidewall; and
forming a first cap layer covering the top electrode and the MTJ structure, wherein the first cap layer comprises:
a first portion covering the first tilted sidewall in a horizontal direction, wherein the first portion is partly located under the first tilted sidewall in the vertical direction; and
a second portion covering the second tilted sidewall in the horizontal direction, wherein the second portion is partly located under the second tilted sidewall in the vertical direction, and a thickness of the first portion in the horizontal direction is greater than a thickness of the second portion in the horizontal direction.

12. The manufacturing method of the memory device according to claim 11, wherein the first portion of the first cap layer comprises a third tilted sidewall and a top surface, the second portion of the first cap layer comprises a fourth tilted sidewall, and the top surface is connected with the third tilted sidewall and the fourth tilted sidewall, respectively.

13. The manufacturing method of the memory device according to claim 12, wherein the third tilted sidewall is located directly under the top surface in the vertical direction, and the fourth tilted sidewall is located directly above the top surface in the vertical direction.

14. The manufacturing method of the memory device according to claim 11, further comprising:
forming a spin-orbit torque (SOT) material above the substrate before the MTJ structure is formed, wherein the MTJ structure and the top electrode are formed above the SOT material, and a method of forming the first cap layer comprises:
forming a cap material covering the SOT material, the MTJ structure, and the top electrode;
forming an oxide mask layer on the cap material; and
performing an etching process using the oxide mask layer as a mask to the cap material and the SOT material, wherein the cap material is patterned to be the first cap layer by the etching process, and the SOT material is patterned to be a SOT layer by the etching process.

15. The manufacturing method of the memory device according to claim 14, wherein the etching process comprises a tilted ion beam etching (IBE) process.

16. The manufacturing method of the memory device according to claim 14, wherein the oxide mask layer comprises a concave sidewall and a curved top surface connected with the concave sidewall, and a width of the curved top surface is greater than a bottom width of the oxide mask layer.

17. The manufacturing method of the memory device according to claim 14, wherein a method of forming the oxide mask layer comprises:
forming an oxide material on the cap material;
forming a patterned mask layer on the oxide material; and
performing a wet etching process using the patterned mask layer as a mask to the oxide material, wherein the oxide material is patterned to be the oxide mask layer by the wet etching process.

18. The manufacturing method of the memory device according to claim 17, wherein the wet etching process comprises a buffer oxide etchant (BOE) etching process.

19. The manufacturing method of the memory device according to claim 14, further comprising:
forming an electrically conductive material above the substrate before the SOT material is formed, wherein the SOT material is formed on the electrically conductive material, and the electrically conductive material is patterned to be a bottom electrode by the etching process; and
forming a second cap layer covering the first cap layer, a fifth tilted sidewall of the SOT layer and a sixth tilted sidewall of the bottom electrode, wherein the second cap layer is partly located under the fifth tilted sidewall in the vertical direction and partly located under the sixth tilted sidewall in the vertical direction.

20. The manufacturing method of the memory device according to claim 19, wherein a top width of the SOT layer is greater than a bottom width of the SOT layer, and a top width of the bottom electrode is greater than a bottom width of the bottom electrode.
